(19) United States
(12) Patent Application Publication
(10) Pub. No.: US 2015/0034010 A1
(43) Pub. Date: Feb. 5, 2015

(54) SUSCEPTOR AND APPARATUS INCLUDING THE SAME

(71) Applicant: SAMSUNG ELECTRONICS CO., LTD., Suwon-si (KR)

(72) Inventors: Su-Ho Lee, Seongnam-si (KR); Su-Hong Kim, Yongin-si (KR); Jung-Wook Kim, Seongnam-si (KR); Dae-Woo Shin, Seoul (KR)

(73) Assignee: SAMSUNG ELECTRONICS CO., LTD., Suwon-si (KR)

(21) Appl. No.: 14/202,605

(22) Filed: Mar. 10, 2014

(30) Foreign Application Priority Data
Aug. 1, 2013 (KR) 10-2013-0091425

(51) Int. Cl. H01L 21/683; H01L 21/02

(52) U.S. Cl. CPC H01L 21/683; H01L 21/02617
USPC 118/723 R; 118/725; 118/500

(57) ABSTRACT

A film deposition apparatus includes a chamber, at least one susceptor disposed inside the chamber and including a seating part, and at least three protrusion parts disposed on the seating part. The seating part is configured to have a wafer seated thereon. The film deposition apparatus further includes a heat source configured to supply heat to the at least one susceptor. The at least three protrusion parts are spaced a distance apart from a center of the at least one susceptor, and the distance is greater than or equal to one third (⅓) of a radius of the wafer seated on the at least one susceptor or greater than or equal to one third (⅓) of a radius of the at least one susceptor.

### CROSS-REFERENCE TO RELATED APPLICATION

This application claims priority from Korean Patent Application No. 10-2013-0091425 filed on Aug. 1, 2013, the disclosure of which is hereby incorporated by reference herein in its entirety.

### 1. TECHNICAL FIELD

The present disclosure relates to a susceptor and a film deposition apparatus including the same, which can reduce a temperature difference over a substrate and allows a film to uniformly grow throughout the substrate when warping of the substrate occurs during growth of the film on the substrate using a high-temperature process.

### 2. DISCUSSION OF THE RELATED ART

In general, semiconductor devices may be manufactured by dividing and packaging individual chips formed on a wafer through various processes, including a deposition process for forming a material film on the wafer, a patterning process, a cleaning process, and so on.

To increase the yield of the manufactured semiconductor devices, a wafer may be used. In general, the wafer has a size ranging from 8 to 12 inches.

To manufacture a semiconductor device, a film may be grown by creating a high temperature environment. To create the high temperature environment, a heat source is provided under a susceptor supporting the wafer.

If the high-temperature process is performed, the warping of the wafer may occur and the wafer may lean to one side due to a difference between components constituting the wafer and the film deposited thereon.

Consequently, a temperature difference may be generated in the wafer, resulting in lowering of film uniformity. To reduce the temperature difference over the wafer, a wafer rotating device may be employed. However, the wafer rotating device may not be able overcome the difficulty associated with the wafer leaning to one side.

In addition, to prevent warping of the wafer from occurring, a bottom portion of the wafer may be seized under vacuum, thereby preventing the wafer from being deformed. However, when a force derived from the deformation of the wafer is larger than the vacuum force, the deformation of the wafer may not be prevented.

### SUMMARY

Exemplary embodiments of the present invention provide a susceptor and a film deposition apparatus including the same, which can increase the temperature uniformity of a wafer when a film deposition process is performed on the wafer at high temperature conditions.

According to an exemplary embodiment of the present invention, there is provided a film deposition apparatus including a chamber, at least one susceptor disposed inside the chamber and including a seating part, and at least three protrusion parts disposed on the seating part. The seating part is configured to have a wafer seated thereon. The thin film deposition apparatus further includes a heat source configured to supply heat to the at least one susceptor. The at least three protrusion parts are spaced a distance apart from a center of the at least one susceptor, and the distance is greater than or equal to one third (⅓) of a radius of the wafer seated on the at least one susceptor or greater than or equal to one third (⅓) of a radius of the at least one susceptor.

According to an exemplary embodiment of the present invention, there is provided a susceptor including a seating part configured to have a wafer seated thereon, and at least three protrusion parts disposed on the seating part. The at least three protrusion parts are spaced a distance apart from a center of the susceptor, and the distance is greater than or equal to one third (⅓) of a radius of the wafer seated on the susceptor or greater than or equal to one third (⅓) of a radius of the susceptor.

According to an exemplary embodiment of the present invention, a film deposition apparatus is provided. The film deposition apparatus includes a chamber including an open top portion, a bottom surface including an exhaust hole therein and a sidewall vertically extending from the bottom surface to define a process space inside the chamber, at least one susceptor disposed inside the chamber and including a seating part and at least three protrusion parts disposed on the seating part and a support axis rotatably coupled to a bottom portion of the seating part. The seating part is configured to have a wafer seated thereon. The at least three protrusion parts are spaced a distance apart from a center of the at least one susceptor, and the distance is greater than or equal to one third (⅓) of a radius of the wafer seated on the at least one susceptor or greater than or equal to one third (⅓) of a radius of the at least one susceptor.

In addition, the film deposition apparatus further includes a heat source configured to supply heat to the at least one susceptor, a lid disposed on the open top portion of the chamber and including a gas intake hole in a top surface thereof which is configured to allow gases for forming plasma to be introduced into the chamber therethough. The lid is configured to seal the inside of the chamber.

Also, the film deposition apparatus further includes at least one shower head disposed between the chamber and the lid, in which the at least one shower head includes a plurality of holes therein which are configured to disperse process gas into the chamber therethrough and an exhaust pipe disposed under the bottom surface of the chamber and coupled to the exhaust hole in the bottom surface of chamber. The exhaust pipe is configured to receive reaction byproducts and gases formed in the process space of the chamber from the exhaust hole and exhaust the reaction byproducts and the gases formed in the process space to outside of the chamber.

As described above, according to exemplary embodiments of the present invention, the temperature uniformity of the wafer can be increased by preventing the wafer from leaning to one side by arranging protrusion parts on a seating part of the susceptor at a distance apart from a center of the suspector of greater than or equal to one third (⅓) of a radius of the wafer.

In addition, increased temperature uniformity of the wafer can be maintained by suppressing the wafer from being affected by heat conduction from the protrusion parts by adjusting lengths and widths of the protrusion parts.

### BRIEF DESCRIPTION OF THE DRAWINGS

Exemplary embodiments of the present invention can be understood in more detail from the following detailed description taken in conjunction with the attached drawings in which:

FIG. 1A illustrates a state in which a wafer is fixed to a susceptor before a high-temperature process is performed, FIG. 1B illustrates a warping phenomenon occurring when a film is deposited on a wafer under a high temperature condition, and FIG. 1C illustrates warping of a wafer occurring in a state in which the wafer leans toward one side when a film is deposited on the wafer under a high temperature condition;

FIG. 2A illustrates a temperature distribution on a wafer when the wafer is uniformly curved, as shown in FIG. 1B, and FIG. 2B illustrates a temperature distribution on a wafer when the wafer leans toward one side to then be curved, as shown in FIG. 1C;

FIG. 3 illustrates a film deposition apparatus according to an exemplary embodiment of the present invention;

FIG. 4 illustrates a configuration of a susceptor including a plurality of protrusion parts according to an exemplary embodiment of the present invention;

FIGS. 5A-5D illustrates in more detail structures of protrusion parts formed on a seating part of a susceptor according to an exemplary embodiment of the present invention;

FIG. 6 illustrates positions of the protrusion parts according to an exemplary embodiment of the present invention;

FIG. 7 illustrates non-uniform temperature distribution of a film deposited on a surface of the wafer when each of the protrusion parts has an area larger than or equal to a reference area;

FIG. 8 illustrates a process of depositing a film using a film deposition apparatus according to an exemplary embodiment of the present invention;

FIG. 9 illustrates a film deposition apparatus according to an exemplary embodiment of the present invention; and

FIG. 10 is a plan view illustrating a support part to which susceptors are fixed according to an exemplary embodiment of the present invention.

### DETAILED DESCRIPTION OF EXEMPLARY EMBODIMENTS

Exemplary embodiments of the present inventive concept and methods of accomplishing the same may be understood more readily by reference to the following detailed description of exemplary embodiments and the accompanying drawings. Like reference numerals refer to like elements throughout the specification.

The terminology used herein is for the purpose of describing particular exemplary embodiments only and is not intended to be limiting of exemplary embodiments of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. As used herein, the term “and/or” includes any and all combinations of one or more of the associated listed items.

Hereinafter, a film deposition apparatus according to an exemplary embodiment of the present invention, which can increase temperature uniformity of a substrate when a film deposition process is performed on a wafer at a high temperature condition, will be described in detail with reference to the accompanying drawings. For the sake of convenient explanation, in the following description, exemplary embodiments of the invention will be described with regard to a wafer exemplified as the substrate.

A process for depositing a film on a surface of a wafer of a semiconductor device is performed under a high temperature condition. When the film deposition process is performed under the high temperature condition, warping of the wafer may occur due to property differences between the film and the wafer, thereby lowering the quality of the film deposited on the wafer.

Hereinafter, the principle in which warping of the wafer occurs in a general semiconductor manufacturing process will be described.

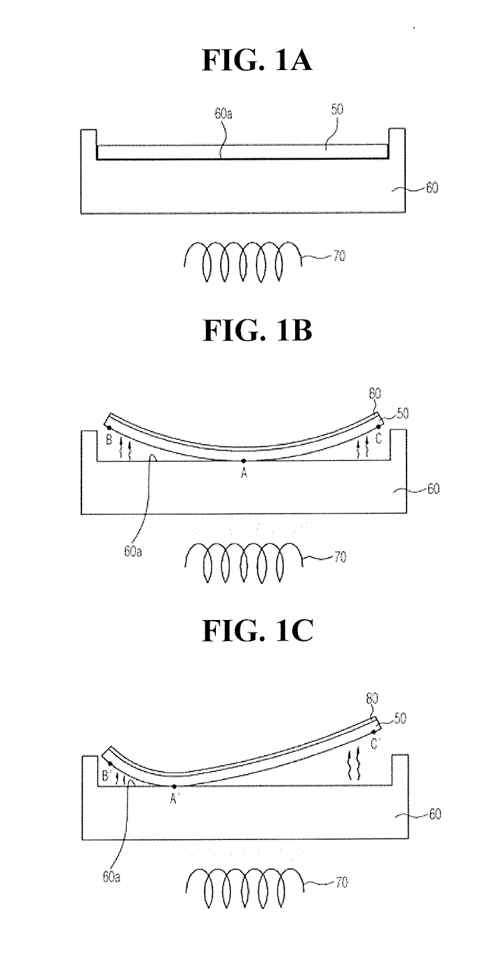

FIG. 1A illustrates a state in which a wafer 50 is fixed to a susceptor 60 before a high-temperature process is performed, FIG. 1B illustrates a warping phenomenon occurring when a film 80 is deposited on a wafer 50 under a high temperature condition, and FIG. 1C illustrates warping of a wafer 50 occurring in a state in which the wafer 50 leans toward one side when a film 80 is deposited on the wafer 50 under a high temperature condition.

Referring to FIG. 1A, a seating part 60a is provided in the susceptor 60, and the wafer 50 is seated on the seating part 60a of the susceptor 60. One surface of the wafer 50 makes contact with the seating part 60a of the susceptor 60 and the other surface of the wafer 50 is exposed to the air. Before a deposition process is performed on the film 80, the wafer 50 is maintained at an initial state in which it is flatly positioned. If the deposition process of the film 80 is initiated, the film 80 is deposited on the exposed portion of the wafer 50 and the flat wafer 50 is deformed due to a high temperature, as shown in FIGS. 1B and 1C.

Referring to FIG. 1B, if the deposition process of the film 80 is initiated at a high temperature, heat is applied to the susceptor 60 through a heat source 70 provided under the susceptor 60, and the heat applied to the susceptor 60 is transferred to the wafer 50 seated on the susceptor 60. The heat is transferred to the wafer 50 by, for example, conduction, convection, or radiation. If the heat is applied to the wafer 50, warping of the wafer 50 may occur due to a difference in properties of component materials forming the wafer 50 and the film 80 deposited on the wafer 50.

If the warping of the wafer 50 occurs, a contact portion A between the wafer 50 and the susceptor 60 and non-contact portions B and C are generated. The heat is transferred to the contact portion A by conduction and is transferred to the non-contact portions B and C by convection or radiation. Thus, a difference in quantities of the heat transferred to the wafer 50 is generated, thereby further accelerating the warping of the wafer 50.

In more detail, conduction refers to a phenomenon in which heat or electricity moves in a material without moving the material. At the contact portion A at which the wafer 50 and the susceptor 60 make contact with each other, conduction occurs to allow for heat movement without moving molecules forming the wafer 50 and the susceptor 60.

In addition, convection refers to a phenomenon in which heat is transferred by the up-and-down movement of fluids due to buoyancy and allows the overall fluids to be uniformly heated by heating bottom portions of the fluids. At the non-contact portions B and C at which the wafer 50 and the susceptor 60 do not make contact with each other, a bottom portion of the fluid positioned between the wafer 50 and the susceptor 60 is heated by the heat of the susceptor 60 heated by the heat source 70 positioned under the susceptor 60, and convection occurs to entirely heat the overall portion of the fluid, thereby transferring the heat the wafer 50 positioned on the susceptor 60.

In addition, radiation refers to a phenomenon in which electromagnetic waves generated when energy is applied to particles are absorbed by other particles to transfer the energy. At the non-contact portions B and C at which the wafer 50 and the susceptor 60 do not make contact with each other, radiation may occur such that the particles between the wafer 50 and the susceptor 60 absorb thermal energy from the susceptor 60 and the absorbed thermal energy is emitted to neighboring atoms in forms of electromagnetic waves to transfer the heat to the wafer 50.

That is to say, heat is transferred between the wafer 50 and the susceptor 60 by conduction, convection, or radiation, and the warping of the wafer 50 is accelerated by a difference in quantities of heat transferred by conduction, convection, or radiation.

Referring to FIG. 1C, if the wafer 50 warping of the wafer 50 occurs, the wafer 50 may lean toward one side to then be curved due to unbalanced weights of materials constituting the wafer 50 or surface conditions of the susceptor 60.

In this case, heat is transferred to the contact portion of the wafer 50 and the susceptor 60 by conduction, while heat is transferred to the non-contact portions of the wafer 50 and the susceptor 60 by convection and radiation. Here, the warping of the wafer 50 may result in an imbalance of quantities of heat transferred to the wafer 50.

In more detail, referring to FIG. 1C, as a portion B′ of the wafer 50 is positioned closer to the susceptor 60 than a portion C′, it is more affected by the heat transferred by convection or radiation than by conduction. Consequently, temperatures of the wafer 50 are partially distributed around the portion A′ and the film 80 deposited on the wafer 50 may be non-uniformly formed.

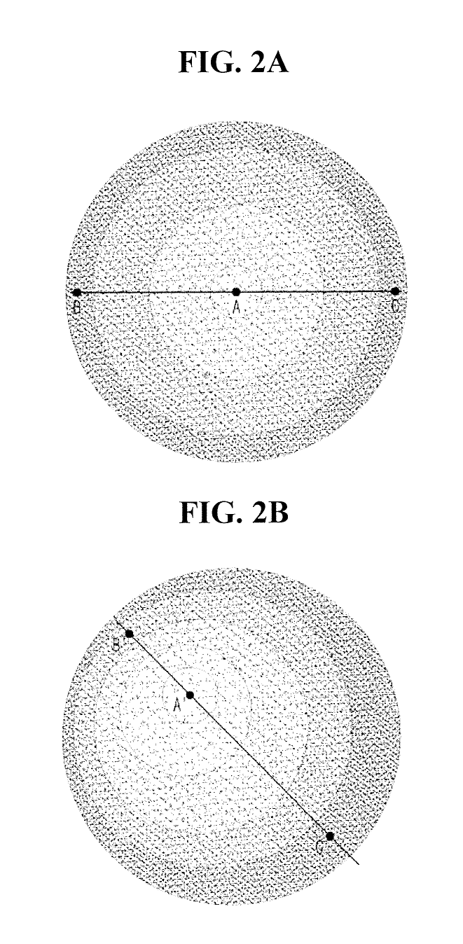

FIG. 2A illustrates a temperature distribution on the wafer 50 when the wafer 50 is uniformly curved, as shown in FIG. 1B, and FIG. 2B illustrates a temperature distribution on the wafer 50 when the wafer 50 leans toward one side to then be curved, as shown in FIG. 1C.

As shown in FIG. 2A, when the wafer 50 is uniformly curved, temperatures of the wafer 50 are uniformly distributed around the portion A, thereby increasing the uniformity of the film 80 deposited on the wafer 50.

As shown in FIG. 2B, when the wafer 50 leans toward one side to then be curved, as shown in FIG. 1C, temperatures of the wafer 50 are partially distributed around the portion A′. That is to say, as the portion B′ of the wafer 50 is positioned closer to the susceptor 60 than the portion C′, it is more affected by the heat transferred by convection or radiation than the portion C′, so that a distribution of higher temperatures is demonstrated. Consequently, uniformity of the film 80 deposited on the wafer 50 may be lowered, compared to a case shown in FIG. 2A.

To solve the above-mentioned difficulty for the purpose of increasing the uniformity of the film 80 deposited on the wafer 50 in a high-temperature process, it may be necessary to prevent the wafer 50 from leaning toward one side. To this end, exemplary embodiments of the present invention provide a film deposition apparatus which is capable of solving the aforementioned difficulty.

Hereinafter, a film deposition apparatus 200 according to an embodiment of the present invention will be described in detail.

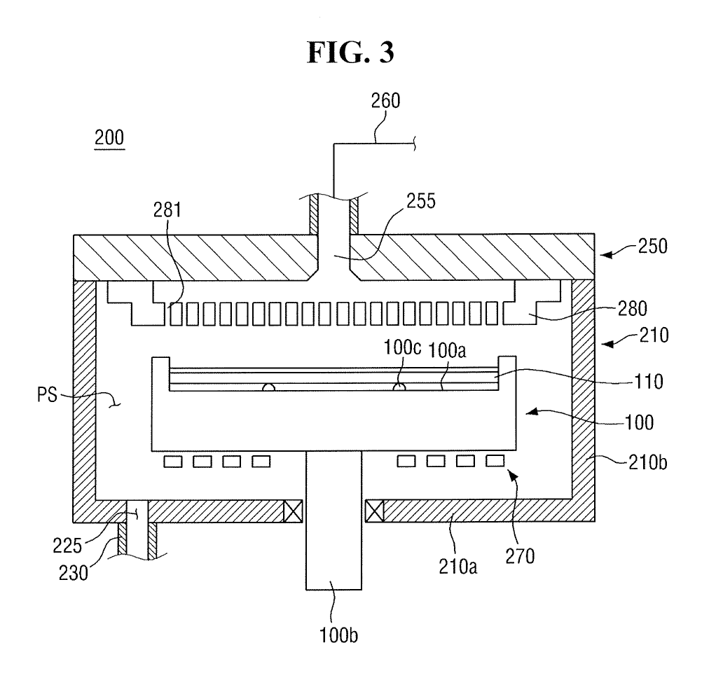

FIG. 3 illustrates a film deposition apparatus 200 according to an embodiment of the present invention.

Referring to FIG. 3, the film deposition apparatus 200 according to the present embodiment of the present invention includes, for example, a chamber 210, at least one susceptor 100 provided inside the chamber 210 and including at least three protrusion parts 100c formed on a seating part 100a, and a heat source 270 supplying heat to the susceptor 100. A wafer 110 is seated on the seating part 100a.

In addition, the film deposition apparatus 200 may also include, for example, a lid 250 provided on the chamber 210 and coupled to the chamber 210 to seal the inside of the chamber 210. A shower head 280 may, for example, further be provided between the chamber 210 and the lid 250.

Hereinafter, for brevity, the film deposition apparatus 200 including one susceptor 100 will be described.

The chamber 210 provides a process space PS in which a process for forming the film 80 takes place. In the present embodiment of the present invention, the chamber 210 may have, for example, an open top portion. In addition, the chamber 210 may have, for example, a bottom surface 210a and a sidewall 210b vertically extending from the bottom surface 210a to form a process space PS.

An exhaust hole 225 may be formed, for example, in the bottom surface 210a of the chamber 210. The exhaust hole 225 may lead, for example, to an exhaust pipe 230 installed under the bottom surface 210a. In the course of depositing the film 80, reaction byproducts and gases formed in the process space PS may be exhausted to the outside through the exhaust hole 225 and the exhaust pipe 230.

A lid 250 may be installed, for example, on a top portion of the chamber 210. In the present embodiment of the present invention, the lid 250 may be, for example, assembled with the chamber 210 to seal the inside of the chamber 210 and may be shaped of for example, a dome or a plane.

In addition, a gas intake hole 255 may be formed, for example, at a central portion of a top surface of the lid 250 to allow gases for forming plasma to be introduced therethrough, and may lead to a gas line 260 providing a process gas. Accordingly, the gas is introduced into the chamber 210 from the gas line 260 through the gas intake hole 255.

A shower head 280 may be provided, for example, between the chamber 210 and the lid 250. The shower head 280 uniformly disperses the process gas into the chamber 210. The shower head 280 is installed, for example, to face a support plate of the susceptor 100 and is made of an insulating material such as, for example, silicon carbide (SiC).

In the present embodiment of the present invention, one shower head 280 is provided. However, alternatively in an embodiment, to ensure process efficiency, a plurality of shower heads 280 may be provided.

A plurality of holes 281 are formed, for example, in the shower head 280. The plasma formed in a plasma forming space is uniformly distributed through the plurality of holes 281 to then be introduced into the chamber 210 and supplied to the wafer 110 seated on the susceptor 100. In the present embodiment of the present invention, each of the plurality of holes 281 has, for example, a circular shape when viewed above a plane. Alternatively, each of the plurality of holes 281 may have other shapes.

The susceptor 100 is installed within the chamber 210. The susceptor 100 is a support member for supporting the wafer 110 and fixes the wafer 110 during a deposition process.

The susceptor 100 may include, for example, the heat source 270, and a additional heat source 270 may be installed under the susceptor 100 to then be exposed to the outside of the susceptor 100.

In addition, the susceptor 100 may include, for example, a seating part 100a on which the wafer 110 is seated and a support axis 100b coupled to a bottom portion of the seating part 100a. While the support axis 100b is basically fixed, it may be rotatably installed about the central axis. The seating part 100a may be rotated according to the rotation of the support axis 100b.

A configuration of the susceptor 100 will now be described in detail.

The susceptor 100 according to the present embodiment of the present invention may have, for example, a circular shape or other shapes. However, for the sake of convenient explanation, the susceptor 100 according to the present embodiment of the present invention will be described assuming that it has a circular shape.

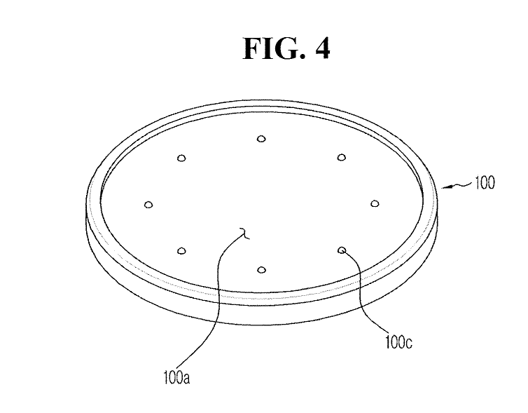

The susceptor 100 is constructed to prevent the wafer 110 from being deformed in a high-temperature process and leaning toward one side. To this end, the susceptor 100 includes, for example, at least three protrusion parts 100c, which are spaced greater than or equal to a predetermined distance apart from the center of the susceptor 100. Each of the protrusion parts 100c may have, for example, an area smaller than or equal to a reference area and a height smaller than or equal to a reference height, which will later be described in detail with reference to FIGS. 4 to 7.

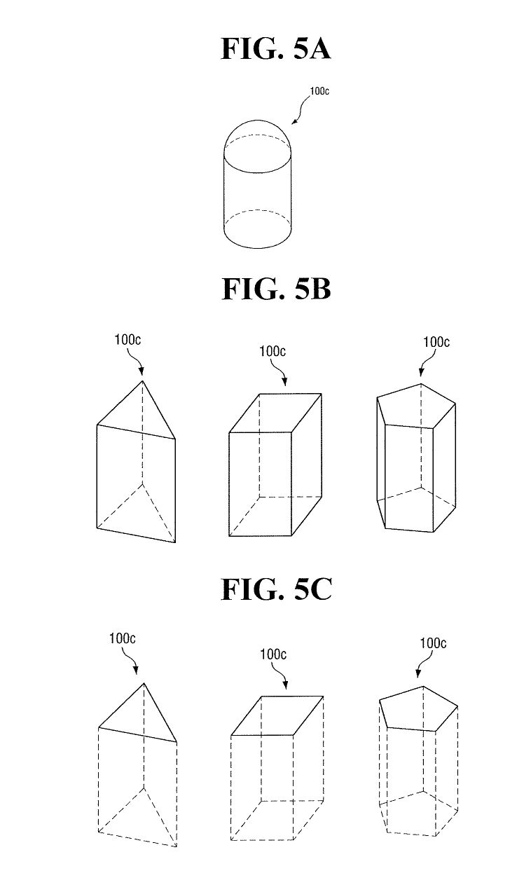

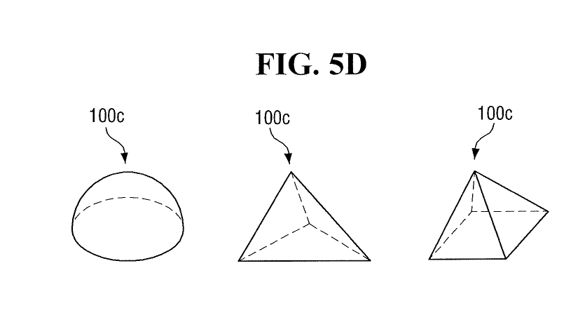

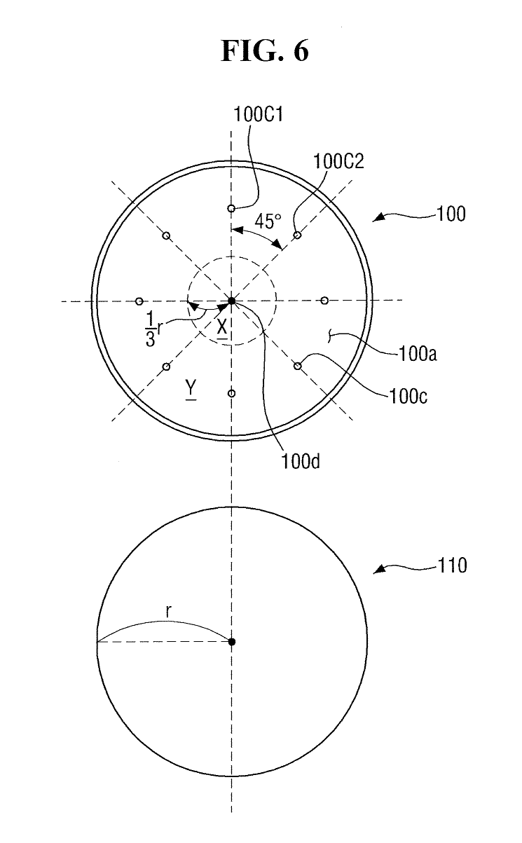

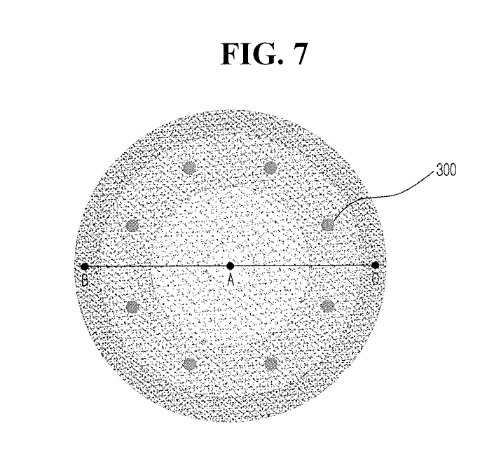

FIG. 4 illustrates a configuration of a susceptor 100 including a plurality of protrusion parts 100c, FIGS. 5A-5D illustrate in more detail structures of the protrusion parts 100c formed on the seating part 100a of the susceptor 100, FIG. 6 illustrates positions of the protrusion parts 100c, and FIG. 7 illustrates non-uniform temperature distribution of a film 80 deposited on a surface of the wafer 110 when each of the protrusion parts 100c has an area larger than or equal to a reference area.

Referring to FIG. 4, the susceptor 100 includes a seating part 100a on which the wafer 110 is seated and at least three protrusion parts 100c provided on the seating part 100a.

The protrusion parts 100c are configured to prevent the wafer 110 seated on the susceptor 100 from being curved and leaning to one side. As only two protrusion parts 100c may not prevent the wafer 110 from leaning, at least three protrusion parts 100c should be provided.

However, if too many protrusion parts 100c are provided, the overall cross-sectional area of the protrusion parts 100c may increase, so that excess heat may be unnecessarily conducted to the wafer 110 due to many contact points between the protrusion parts 100c and the wafer 110, thereby impairing the temperature uniformity of the film 80 deposited on the wafer 110. Therefore, it may be necessary to form an appropriate number of protrusion parts 100c. In light of the foregoing, generally, for example, 8 to 12 protrusion parts 100c are formed.

Referring to FIG. 5A, the protrusion part 100c has, for example, a cylindrical body and a hemispherical head.

However, the body of the protrusion part 100c is not limited to the cylindrical body. Rather, the body of the protrusion part 100c may be shaped of, for example, a triangular box, a square box, a pentagonal box, and so on, as shown in FIG. 5B, and the head of the protrusion part 100c may be shaped of, for example, a truncated triangle, a truncated square, a truncated pentagon, and so on, as shown in FIG. 5C.

In addition, as shown in FIG. 5D, the protrusion part 100c may have, for example, only a head shaped of a hemisphere, a triangular pyramid, or a quadrangular pyramid without forming a box-shaped body.

The protrusion parts 100c are, for example, spaced apart from the center of the susceptor 100. For example, a distance between each of the protrusion parts 100c and the center of the susceptor 100 may be greater than or equal to one third (⅓) of a radius of the wafer 110 to be seated on the susceptor 100 from the center of the susceptor 100 or may be greater than or equal to ⅓ of the radius of the susceptor 100.

However, it was experimentally confirmed that it was possible to effectively prevent the wafer 110 from leaning to one side when the distance between the protrusion parts 100c and the center of the susceptor 100 is greater than or equal to one third (⅓) of the radius of the wafer 110 seated on the susceptor 100. Therefore, the distance between the protrusion parts 100c and the center of the susceptor 100 should be greater than or equal to one third (⅓) of the radius of the wafer 110 to be seated on the susceptor 100.

Hereinafter, for the sake of convenient explanation, exemplary embodiments of the present invention will be described with regard to a case where the distance between the protrusion parts 100c and the center of the susceptor 100 is greater than or equal to one third (⅓) of the radius of the wafer 110 seated on the susceptor 100.

Referring to FIG. 6, a region X of the susceptor 100 is a region in which the radius of the wafer 110 seated on the susceptor 100 is ⅓ or less, and the protrusion parts 100c are not included in the region X. A region Y of the susceptor 100 is a region in which the radius of the wafer 110 seated on the susceptor 100 is greater than or equal to ⅓ of the radius of the wafer 110, and the protrusion parts 100c are included in the region Y.

The distance of the wafer 110 being greater than or equal to ⅓ of the radius of the wafer 110 is experimentally determined, and the protrusion parts 100c are provided for the purpose of preventing the wafer 110 from leaning to one side when the wafer 110 is curved. To effectively prevent the wafer 110 from leaning to one side, the distance between the protrusion parts 100c and the center of the susceptor 100 should be greater than or equal to ⅓ of the radius of the wafer 110 seated on the susceptor 100.

Distances between the center of the susceptor 100 and the respective protrusion parts 100c may be equal to each other or may be different from each other. Here, to allow the protrusion parts 100c to more effectively prevent the wafer 110 from leaning, the distances between the center of the susceptor 100 and the respective protrusion parts 100c should be equal to each other.

As an exemplary embodiment of the present invention, appropriate locations of the protrusion parts 100c will be described with regard to a case where 8 protrusion parts 100c are formed on the seating part 100a of the susceptor 100.

In the case where 8 protrusion parts 100c are formed on the seating part 100a of the susceptor 100, they should be equidistantly spaced apart from the center 100d of the susceptor 100, and the distance between the protrusion parts 100c and the center 110d of the susceptor 100 should be greater than or equal to ⅓ of the radius of the wafer 110 seated on the susceptor 100. In addition, to support the wafer 110 with a uniform force, the protrusion parts 100c should be arranged such that an angle formed by a particular protrusion part 100c1, the center 100d of the susceptor 100 and another particular protrusion part 100c2 is about 45 degrees (=360°/8).

Referring to FIG. 7, when a cross-sectional area of each of the protrusion parts 100c provided on the seating part 100a of the susceptor 100 is larger than or equal to a reference area or when a height of each of the protrusion parts 100c is equal to or smaller than a reference height, temperature distribution of the wafer 110 may become non-uniform. That is to say, as shown in FIG. 7 illustrating temperature distribution of a film deposited on the wafer, dot-shaped patterns 300 are formed on contact portions between the protrusion parts 100c and the wafer 110.

The dot-shaped patterns 300 are formed when the wafer 110 is affected more by the heat conducted by the protrusion parts 100c than by the heat derived on convection by the susceptor 100. When a cross-sectional area of each of the protrusion parts 100c is larger than a reference area or when a height of each of the protrusion parts 100c is larger than or equal to a reference height, the wafer 110 may be significantly affected by the heat conducted by the protrusion parts 100c, and the dot-shaped patterns 300 are thus formed.

In more detail, if the cross-sectional area of each of the protrusion parts 100c is smaller than or equal to the reference area, heat conduction between the protrusion parts 100c and the wafer 110 may be negligible. However, if the cross-sectional area of each of the protrusion parts 100c is larger than the reference area, heat conduction by the protrusion parts 100c, affecting the wafer 110, may not be ignored.

In addition, if the height of each of the protrusion parts 100c is larger than or equal to the reference height, a difference between the influence of the heat by conduction occurring at contact portions between the protrusion parts 100c and the wafer 110 and the influence of the heat by convection occurring between the susceptor 100 and the wafer 110 spaced apart from each other, may be negligible. However, if the height of each of the protrusion parts 100c is smaller than or equal to the reference height, the influence of the heat by conduction occurring at contact portions between the protrusion parts 100c and the wafer 110 may be greater than the influence of the heat by convection occurring between the susceptor 100 and the wafer 110 spaced apart from each other. Thus, the influence of the conduction of heat transferred from the protrusion parts 100c to the wafer 110 may not be ignored.

Eventually, if the wafer 110 is affected by the heat transferred from the protrusion parts 100c, the film 80 may not be uniformly deposited on the wafer 110, thereby lowering the product quality. Accordingly, the cross-sectional area of each of the protrusion parts 100c should be smaller than or equal to the reference area and the height of each of the protrusion parts 100c is smaller than or equal to the reference height.

As experimentally confirmed, the maximum area of each of the protrusion parts 100c, which can minimize the influence of heat conduction from the protrusion parts 100c to the wafer 110, is 3 mm². Thus, the cross-sectional area of each of the protrusion parts 100c should be greater than 0 mm² and not greater than 3 mm².

In addition, as experimentally confirmed, the maximum height of each of the protrusion parts 100c, which can minimize the difference between the influence of the heat by conduction occurring at contact portions between the protrusion parts 100c and the wafer 110 and the influence of the heat by convection occurring between the susceptor 100 and the wafer 110 spaced apart from each other, is 200 μm. Thus, the height of each of the protrusion parts 100c should be greater than 0 μm and not greater than 200 μm.

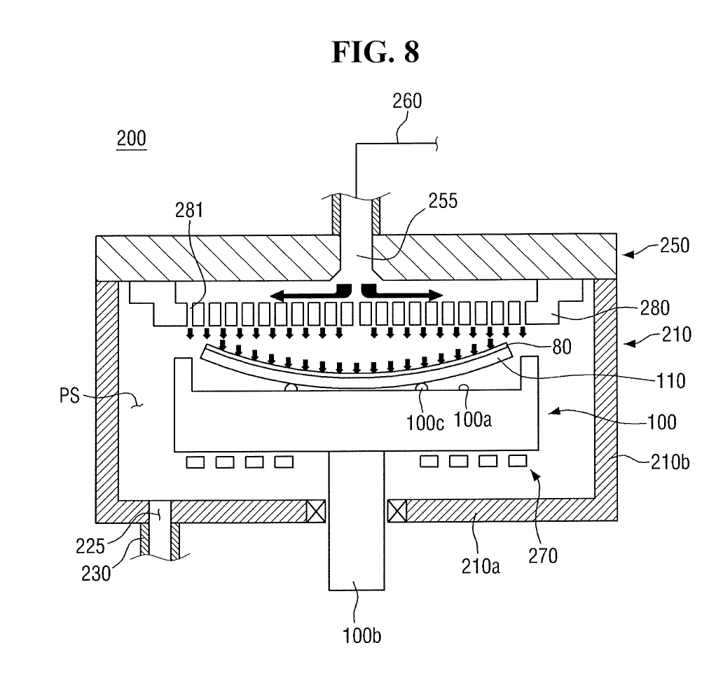

FIG. 8 illustrates a process of depositing the film 80 using the film deposition apparatus 200 shown in FIG. 3. Referring to FIG. 8, the wafer 110 is first seated on the seating part 100a of the susceptor 100. Next, a process gas is introduced through a gas intake hole 255. Specifically, the process gas is introduced to the inside of the lid 250, uniformly mixed and filtered by the shower head 280 to then be introduced into the chamber 210.

The process gas introduced into the chamber 210 is supplied to the wafer 110, and the film 80 is deposited on the wafer 110 accordingly.

In the course of depositing the film 80 on the wafer 110, the heat source 270 provided in the susceptor 100 supplies heat to the susceptor 100, and the heat is transferred to the wafer 110 by conduction or convection.

If the heat is supplied to the wafer 110, deformation, e.g., warping, occurs to the wafer 110 due to a difference between components constituting the film 80 deposited on the wafer 110.

However, the wafer 110 may not lean to one side because the protrusion parts 100c provided on the seating part 100a of the susceptor 100 serve to support the wafer 110.

Consequently, uniformity of the film 80 deposited on the wafer 110 can be increased, and a defect rate in device production can be lowered owing to the increased uniformity of the film 80.

Hereinafter, a film deposition apparatus 400 according to an embodiment of the present invention will be described.

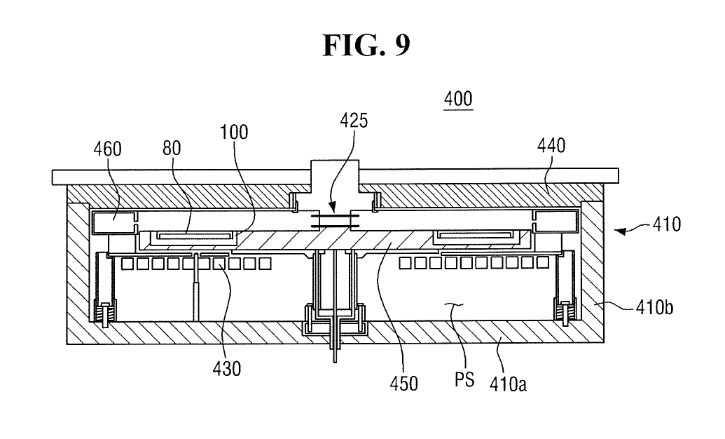

FIG. 9 illustrates a film deposition apparatus 400 according to an embodiment of the present invention.

Referring to FIG. 9, the film deposition apparatus 400 according to the present embodiment of the present invention includes, for example, a chamber 410, at least one susceptor 100 provided inside the chamber 410 and including at least three protrusion parts 100c formed on a seating part 100a, and a heat source 430 provided to supply heat to the susceptor 100. A wafer 110 is seated on the seating part 100a.

In addition, the film deposition apparatus 400 may further include, for example, a lid 440 provided on the chamber 410 and coupled to the chamber 410 to seal the inside of the chamber 410, and a support part 450 supporting the susceptor 100.

Hereinafter, for the sake of convenient explanation, the present embodiment of the present invention will be described with regard to the film deposition apparatus 400 including a plurality of susceptors 100 provided on the support part 450.

The chamber 410 provides a process space PS in which a process for depositing the film 80 takes place. In the present embodiment of the present invention, the chamber 410 may have, for example, an open top portion. In addition, the chamber 410 may have, for example, a bottom surface 410a and a sidewall 410b vertically extending from the bottom surface 410a to form the process space PS. An exhaust hole 460 may be formed, for example, in a lateral surface of the chamber 410. In the course of depositing the film 80, reaction byproducts and gases formed in the process space PS may be exhausted to the outside through the exhaust hole 460.

A lid 440 may be installed, for example, on a top portion of the chamber 410. In the present embodiment of the present invention, the lid 440 may be assembled, for example, with the chamber 410 to seal the inside of the chamber 410 and may be shaped of a dome or a plane.

In addition, a gas intake hole 425 may be formed, for example, at a central portion of a top surface of the lid 440 to allow a process gas to be introduced into the chamber 410.

The support part 450 is installed inside the chamber 410. The support part 450, which is a support member for supporting the susceptors 100, fixes the susceptors 100.

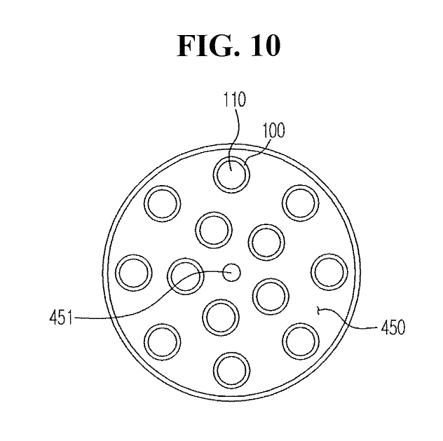

FIG. 10 is a plan view illustrating a support part 450 to which susceptors 100 are fixed.

Referring to FIG. 10, the support part 450 according to the present embodiment of the present invention is shaped of, for example, a disk, and the susceptors 100 on each of which the wafer 110 is seated are, for example, circumferentially arranged in sequence about a central axis 451 of the support part 450. However, the shape of the support part 450 and arrangement of the susceptors 100 seated on the support part 450 are not limited to those illustrated herein and may vary as long as they can be readily embodied by one skilled in the art.

The susceptors 100 are provided on the support part 450 and are arranged to be opposite to and face the process gas intake hole 425.

The susceptors 100 for mounting the wafers 110 include, for example, protrusion parts 110c for increasing temperature uniformity of the wafer 110 during the depositing process.

In more detail, as described above with reference to FIGS. 4 to 7, each of the susceptors 100 should include at least three protrusion parts 100c, and each of the protrusion parts 100c included in each of the susceptors 100 may have, for example, a cylindrical body and a hemispherical head. In addition, the protrusion parts 100c should be spaced greater than or equal to a predetermined distance apart from the center 100d of each of the susceptors 100. A cross-sectional area of each of the protrusion parts 100c should be smaller than or equal to a reference area, and a height of each of the protrusion parts 100c should be smaller than or equal to a reference height.

During the depositing process of the film 80 according to the present embodiment of the present invention, the process gas introduced into the chamber 410 is supplied to the wafer 110, and the film 80 is deposited on the wafer 110 accordingly.

In the course of depositing the film 80 on the wafer 110, the heat source 430 provided in each of the susceptors 100 supplies heat to the susceptors 100, and the heat is transferred to the wafer 110 by conduction or convection.

If the heat is supplied to the wafer 110, deformation, e.g., warping, occurs to the wafer 110 due to a difference between components constituting the film 80 deposited on the wafer 110.

However, the wafer 110 may not lean to one side because the protrusion parts 100c provided on the seating part 100a of each of the susceptors 100 serve to support the wafer 110.

Consequently, the uniformity of the film 80 deposited on the wafer 110 can be increased, and a defect rate in device production can be lowered owing to the increased uniformity of the film 80.

Hereinafter, a susceptor 100 according to an embodiment of the present invention will now be described in detail.

The susceptor 100 according to the present embodiment of the present invention may have, for example, a circular shape or other shapes. The susceptor 100 is constructed to prevent the wafer 110 from being deformed in a high-temperature process and leaning toward one side.

To this end, the susceptor 100 includes at least three protrusion parts 100c. The number, shapes, locations, areas and heights of the protrusion parts 100c provided on the susceptor 100 will now be described in detail.

The number of the protrusion parts 100c according to the present embodiment of the present invention is at least three. The protrusion parts 100c are provided for the purpose of preventing the wafer 110 seated on the susceptor 100 from leaning to one side when the wafer 110 is curved. As the leaning of the wafer 110 may not be prevented using only two protrusion parts 100c, at least three protrusion parts 100c should be provided to effectively prevent the wafer 110 seated on the susceptor 100 from leaning to one side.

In a case where only three protrusion parts 100c are formed, and the wafer 110 still cannot be effectively supported, it may necessary to form more than three protrusion parts 100c. However, if too many protrusion parts 100c are provided, the overall cross-sectional area of the protrusion parts 100c may increase, so that excess heat may be unnecessarily conducted to the wafer 110 due to many contact points between the protrusion parts 100c and the wafer 110, thereby impairing temperature uniformity of the film 80 deposited on the wafer 110. In light of the foregoing, generally, for example, 8 to 12 protrusion parts 100c should be formed.

Each of the protrusion part 100c according to the present embodiment of the present invention has, for example, a cylindrical body and a hemispherical head.

However, the body of each of the protrusion parts 100c is not limited to the cylindrical body. Rather, in an embodiment, the body of the protrusion part 100c may be shaped of, for example, a triangular box, a square box, a pentagonal box, and so on, and the head of the protrusion part 100c may be shaped of, for example, a truncated triangle, a truncated square, a truncated pentagon, and so on, which is the same as described above.

Distances between the center of the susceptor 100 and the respective protrusion parts 100c may be equal to each other or may be different from each other. Here, to allow the protrusion parts 100c to more effectively prevent the wafer 110 from leaning to one side, the distances between the center of the susceptor 100 and the respective protrusion parts 100c should be equal to each other.

As one exemplary embodiment of the present invention, appropriate locations of the protrusion parts 100c will be described with regard to a case where 8 protrusion parts 100c are formed on the seating part 100a of the susceptor 100.

In the case where 8 protrusion parts 100c are formed on the seating part 100a of the susceptor 100, they should be equidistantly spaced apart from the center 110d of the susceptor 100, and the distance between the protrusion parts 100c and the center 110d of the susceptor 100 should be greater than or equal to ⅓ of the radius of the wafer 110 seated on the susceptor 100. In addition, to support the wafer 110 with a uniform force, the protrusion parts 100 should be arranged such that an angle formed by a particular protrusion part 100c1, the center 100d of the susceptor 100 and another particular protrusion part 100c2 is about 45 degrees (=360°/8).

In addition, the protrusion parts 100c according to an embodiment of the present invention are spaced apart from the center 100d of the susceptor 100, and a distance between each of the protrusion parts 100c and the center 100d of the susceptor 100 may be greater than or equal to ⅓ of the radius of the susceptor 100.

The cross-sectional area of each of the protrusion parts 100c should be greater than 0 mm² and not greater than 3 mm², and the height of each of the protrusion parts 100c should be greater than 0 μm and not greater than 200 μm.

The numerical values stated above are standard values determined through experimentation. When the area of each of the protrusion parts 100c is greater than 0 mm² and not greater than 3 mm² or when the height of each of the protrusion parts 100c is greater than 0 μm and not greater than 200 μm, the wafer 110 is less affected by the heat conducted from the protrusion parts 100c, thereby increasing the uniformity of the film 80 deposited on the wafer 110.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. A film deposition apparatus comprising:
a chamber;
at least one susceptor disposed inside the chamber and including a seating part, at least three protrusion parts disposed on the seating part, wherein the seating part is configured to have a wafer seated thereon; and
a heat source configured to supply heat to the at least one susceptor,
wherein the at least three protrusion parts are spaced a distance apart from a center of the at least one susceptor, and wherein the distance is greater than or equal to one third (⅓) of a radius of the wafer seated on the at least one susceptor or greater than or equal to one third (⅓) of a radius of the at least one susceptor.

2. The film deposition apparatus of claim 1, wherein each of the at least three protrusion parts has a cross-sectional area of greater than 0 mm² and not greater than 3 mm².

3. The film deposition apparatus of claim 1, wherein each of the at least three protrusion parts has a height of greater than 0 μm and not greater than 200 μm.

4. The film deposition apparatus of claim 1, wherein the at least three protrusion parts have a uniform height.

5. The film deposition apparatus of claim 1, further comprising a lid disposed on the chamber and coupled to the chamber to seal the inside of the chamber.

6. The film deposition apparatus of claim 1, further comprising a support part supporting the at least one susceptor.

7. A susceptor comprising:
a seating part configured to have a wafer seated thereon; and
at least three protrusion parts disposed on the seating part,
wherein the at least three protrusion parts are spaced a distance apart from a center of the susceptor, and wherein the distance is greater than or equal to one third (⅓) of a radius of the wafer seated on the susceptor or greater than or equal to one third (⅓) of a radius of the susceptor.

8. The susceptor of claim 7, wherein each of the at least three protrusion parts has a cross-sectional area of greater than 0 mm² and not greater than 3 mm².

9. The susceptor of claim 7, wherein each of the at least three protrusion parts has a height of greater than 0 μm and not greater than 200 μm.

10. The susceptor of claim 7, wherein the at least three protrusion parts have a uniform height.

11. A film deposition apparatus comprising:
a chamber including an open top portion, a bottom surface including an exhaust hole therein and a sidewall vertically extending from the bottom surface to define a process space inside the chamber;
at least one susceptor disposed inside the chamber and including a seating part and at least three protrusion parts disposed on the seating part and a support axis rotatably coupled to a bottom portion of the seating part, wherein the seating part is configured to have a wafer seated thereon, wherein the at least three protrusion parts are spaced a distance apart from a center of the at least one susceptor, and wherein the distance is greater than or equal to one third (⅓) of a radius of the wafer seated on the at least one susceptor or greater than or equal to one third (⅓) of a radius of the at least one susceptor;
a heat source configured to supply heat to the at least one susceptor;
a lid disposed on the open top portion of the chamber and including a gas intake hole in a top surface thereof which is configured to allow gases for forming plasma to be introduced into the chamber therethough, wherein the lid is configured to seal the inside of the chamber;
at least one shower head disposed between the chamber and the lid, wherein the at least one shower head includes a plurality of holes therein which are configured to disperse process gas into the chamber therethrough; and
an exhaust pipe disposed under the bottom surface of the chamber and coupled to the exhaust hole in the bottom surface of chamber, wherein the exhaust pipe is configured to receive reaction byproducts and gases formed in the process space of the chamber from the exhaust hole and exhaust the reaction byproducts and the gases formed in the process space to outside of the chamber.

12. The film deposition apparatus of claim 11, further comprising a gas line coupled to the gas intake hole and configured to supply the process gas into the chamber through the gas intake hole.

13. The film deposition apparatus of claim 11, wherein the distances between the center of the at least one suspector and the at least three protrusion parts are equal to each other.

14. The film deposition apparatus of claim 11, wherein the at least one shower head includes a plurality of shower heads.

15. The film deposition apparatus of claim 11, wherein the at least three protrusion parts each have a cylindrical shaped body and a hemispherical shaped head.

16. The film deposition apparatus of claim 11, wherein a body of each the at least three protrusion parts comprises a shape selected from the group consisting of a triangular box, a square box or a pentagonal box.

17. The film deposition apparatus of claim 16, wherein a head of each the at least three protrusion parts comprises a shape selected from the group consisting of a truncated triangle, a truncated square or a truncated pentagon.

18. The film deposition apparatus of claim 11, wherein a head of each the at least three protrusion parts comprises a shape selected from the group consisting of a hemisphere, a triangular pyramid, or a quadrangular pyramid.

19. The film deposition apparatus of claim 11, wherein the at least three protrusion parts includes eight to twelve protrusion parts.

20. The film deposition apparatus of claim 11, wherein the plurality of holes disposed in the shower head each have a circular shape when viewed above a plane.
